(19) United States
(12) Patent Application Publication
(10) Pub. No.: US 2024/0347736 A1
(43) Pub. Date: Oct. 17, 2024

(54) ELECTRODE HAVING CURRENT COLLECTOR THAT HAS THREE-DIMENSIONAL STRUCTURE, AND BATTERY USING SAME

(71) Applicant: THE INDUSTRY & ACADEMIC COOPERATION IN CHUNGNAM NATIONAL UNIVERSITY, Daejeon (KR)

(72) Inventor: Jong Myung WOO, Daejeon (KR)

(73) Assignee: THE INDUSTRY & ACADEMIC COOPERATION IN CHUNGNAM NATIONAL UNIVERSITY, Daejeon (KR)

(21) Appl. No.: 18/294,536

(22) PCT Filed: Mar. 15, 2022
(86) PCT No.: PCT/KR2022/003591

§ 371 Date: Mar. 29, 2024

(30) Foreign Application Priority Data
Aug. 2, 2021 (KR) 10-2021-0101367

(51) Int. Cl. H01M 4/70; H01M 10/0525; H01M 10/44

(52) U.S. Cl. CPC H01M 4/70; H01M 10/0525; H01M 10/44

(57) ABSTRACT

The present invention comprises a pair of current collectors positioned parallel to each other at a predetermined interval, wherein the pair of current collectors have a three-dimensional sharp protrusion structure formed on the surface thereof, so that the charge distribution is concentrated on the three-dimensional sharp protrusion structure to increase the charging capacity per unit area of a battery.

### TECHNICAL FIELD

The present disclosure relates to an electrode having a current collector that has a three-dimensional structure, and relates to a battery using the electrode. Particularly, the present disclosure relates to an electrode having a current collector having a three-dimensional sharp protrusion structure such that the amount of charges (or ions) accumulated on the current collector per unit area is increased so that a battery capacity is capable of being increased, and relates to a battery using the electrode.

### BACKGROUND ART

A battery uses an electrolyte in a liquid type or a solid type, the electrolyte being one of key components of a lithium-ion battery. When an electrolyte of a lithium-ion battery is solidified, stability may be increased. The lithium-ion battery is a mainstream of the current battery market. However, since a liquid electrolyte is applied to the battery, an explosion or a fire may occur when an expansion of the battery due to a temperature change or a leakage due to an external impact occurs. On the other hand, in an all-solid-state battery having an electrolyte in a solid type, lithium metal that was not used as a negative electrode material due to the risk of explosion is capable of being used as a negative electrode material cathode material, and the energy density may be significantly increased compared to a conventional battery using graphite. In addition, since the structure of an all-solid-state battery is hard and stable, a shape of the structure is maintained even if the electrolyte is damaged, so that there is an advantage that the stability is high. Therefore, an all-solid-state battery is easily used to increase a driving distance of an electric vehicle. That is, an all-solid-state battery is easily used to increase energy density of a battery for an electric vehicle.

However, such an electrolyte in a liquid state or a solid state is in contact with a current collector having a plane shape. A battery capacity is determined in proportion to the total area of the current collector having the plane shape. Therefore, a technology of increasing the battery capacity by maximizing the amount of charges (ions) accumulated per unit area in the current collector is required.

Related to this technology, in Korean Patent No. 10-2180259, an aluminum base for a current collector, a current collector using the aluminum base, a positive electrode using the aluminum base, a negative electrode using the aluminum base, and a secondary battery using the aluminum base are disclosed. In the related patent document, the capacity maintenance rate and the cycle characteristics may be improved by using the current collector using the aluminum substrate that has a rough surface.

As another related technology (Seo Bo-Hyun, Hong Ji-Hoon, Woo Jong-myong, “Monopole Antenna for EMP Defense”, 2018 Summer Institute of Electromagnetic Engineering and Science), FIG. 1 illustrates a monopole antenna having a sharp protrusion structure. Referring to FIG. 1, when an external high power is applied to the monopole antenna, the monopole antenna in which a power supply monopole is positioned on a ground surface and a cylinder having a larger radius is covered and then an external high power electromagnetic wave is induced so that the external high power electromagnetic wave is transferred to an internal receiver in a non-contact coupling manner with the internal power supply monopole is provided. At this time, there is a risk that an internal signal receiving system may be destroyed when a high output power electromagnetic wave from the outside is applied. FIG. 2 shows a sharp protrusion structure of a monopole antenna. Referring to FIG. 2, in order to prevent the destruction of the internal signal receiving system from the high output power electromagnetic wave from the outside, a structure in which a lower end of an outer conductor has a flat shape and a structure in which a lower end of an outer conductor has a sharp shape are formed. FIG. 3 shows a high output power generating apparatus for connecting a sharp protrusion structure to a monopole antenna. Referring to FIG. 3, the sharp protrusion structure may be connected to a cylindrical conductor outside an antenna and to a ground surface by using the high output power generating apparatus.

As described above, rather than a plane structure applied in a current collector, a method of increasing the battery capacity by increasing the amount of charges (ions) per unit area by increasing the area per unit area by using a three-dimensional structure is disclosed. However, a method for maximizing the amount of charges (ions) accumulated on a current collector having a limited area by using a three-dimensional sharp protrusion structure such that an electrostatic characteristic is improved is not disclosed.

### DOCUMENT OF RELATED ART

### Patent Document

(Patent Document 1) Korean Patent No. 10-2180259

### DISCLOSURE

### Technical Problem

Accordingly, the present disclosure has been made keeping in mind the above problems occurring in the related art, and an objective of the present disclosure is to provide an electrode having a current collector that has a three-dimensional structure and a battery using the electrode, the electrode being capable of maximizing the transfer of charges (ions) per unit area by having a sharp three-dimensional protrusion structure on a surface of a current collector that has a plane shape.

### Technical Solution

In order to achieve the objective described above, there is provided an electrode having a current collector that has a three-dimensional structure, the electrode including: a pair of current collectors positioned parallel to each other at a predetermined interval, wherein a three-dimensional sharp protrusion structure is formed on surfaces of the pair of current collectors, so that a charge distribution is concentrated on the three-dimensional sharp protrusion structure, thereby increasing a charging capacity per unit area of a battery.

Preferably, the three-dimensional sharp protrusion structure having a tack shape may be formed on the surfaces of the pair of current collectors.

Preferably, the three-dimensional sharp protrusion structure having a T-shape may be formed on the surfaces of the pair of current collectors.

Preferably, the three-dimensional sharp protrusion structure having a dispersed shape may be formed on the surfaces of the pair of current collectors.

In addition, in the present disclosure, there is provided a battery using an electrode having a current collector that has a three-dimensional structure, the battery including: a pair of current collectors positioned parallel to each other at a predetermined interval; and an electrolyte positioned between the pair of current collectors, the electrolyte being in contact with the pair of current collectors, wherein a three-dimensional sharp protrusion structure is formed on surfaces of the pair of current collectors, so that a charge distribution is concentrated on the three-dimensional sharp protrusion structure, thereby increasing a charging capacity per unit area.

### Advantageous Effects

According to the present disclosure, there is an advantage that the transfer of charges (ions) per unit area may be maximized by using a characteristic that charges (ions) are concentrated on a sharp structure by transforming the surface of the current collector having a plane shape such that the three-dimensional sharp structure is formed.

In addition, there is an advantage that the present disclosure may be utilized as a technology capable of improving the performance a battery that is to be applied to an electric vehicle and so on.

### DESCRIPTION OF DRAWINGS

FIG. 1 illustrates a monopole antenna having a sharp protrusion structure.

FIG. 2 shows a sharp protrusion structure of a monopole antenna.

FIG. 3 shows a high output power generating apparatus for connecting a sharp protrusion structure to a monopole antenna.

FIG. 4 is a view illustrating a configuration of an electrode having a current collector that has a three-dimensional structure according to an embodiment of the present disclosure.

FIG. 5 is a graph showing an output voltage according to an input voltage applied to a monopole antenna when an interval between sharp end portions is 1 mm.

FIG. 6 is a graph showing a voltage at the time of discharge according to the presence or absence of a sharp end portion structure.

FIG. 7 shows an electrode in which a sharp protrusion structure having a three-dimensional tack shape is formed on surfaces of a current collector according to an embodiment of the present disclosure.

FIG. 8 shows an electrode in which a sharp protrusion structure having a three-dimensional T-shape is formed on the surfaces of the current collector according to an embodiment of the present disclosure.

FIG. 9 is shows an in which a sharp protrusion structure having a three-dimensional dispersed shape is formed on the surface of the current collector according to an embodiment of the present disclosure.

FIG. 10 is a view illustrating a configuration of a battery using an electrode having a current collector that has a three-dimensional structure according to an embodiment of the present disclosure.

FIG. 11 shows a battery using an electrode in which a sharp protrusion structure having a three-dimensional tack shape is formed on the surface of a current collector according to an embodiment of the present disclosure.

FIG. 12 shows a battery using an electrode in which a sharp protrusion structure having a three-dimensional T-shape is formed on a surface of a current collector according to an embodiment of the present disclosure.

FIG. 13 shows a battery using an electrode in which a sharp protrusion structure having a three-dimensional dispersed shape is formed on a surface of a current collector according to an embodiment of the present disclosure.

FIG. 14 is a view illustrating a configuration of a battery in which a current collector structure according to an embodiment of the present disclosure is illustrated in a plane shape.

FIG. 15 is a view illustrating a configuration of batteries having a current collector that has a three-dimensional structure according to an embodiment of the present disclosure.

FIG. 16 is a view illustrating a configuration of a solar cell having a current collector that has a three-dimensional structure according to an embodiment of the present disclosure.

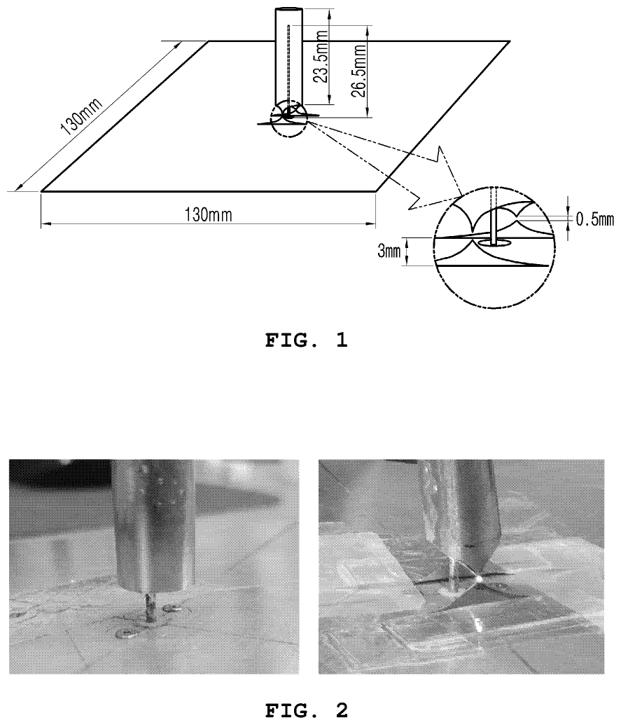

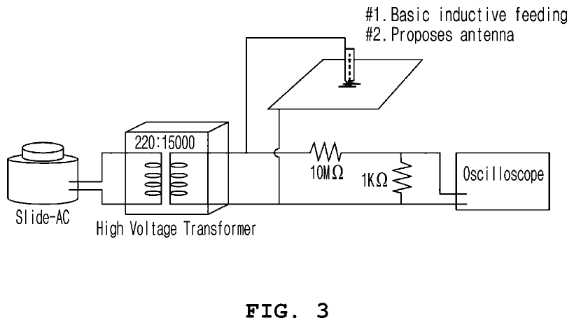

### MODE FOR INVENTION

Hereinafter, the present disclosure will be described in detail with reference to the contents described in the accompanying drawings. However, the present disclosure is not limited or restricted by exemplary embodiments. Same reference numerals presented in each drawing represent members that perform substantially the same function.

Objectives and effects of the present disclosure may be naturally understood or more clearly understood according to the following description, and the objectives and the effects of the present disclosure are not limited to the following description. In addition, in describing the present disclosure, when it is determined that a detailed description of a known technology related to the present disclosure may unnecessarily obscure the subject matter of the present disclosure, the detailed description will be omitted.

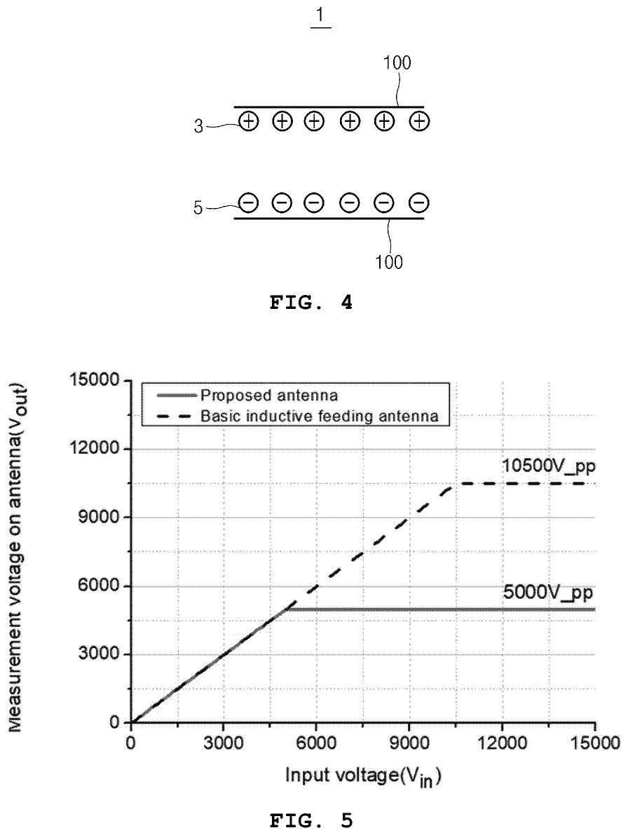

FIG. 4 is a view illustrating a configuration of an electrode 1 having a current collector that has a three-dimensional structure according to an embodiment of the present disclosure. Referring to FIG. 4, the electrode 1 having the current collector that has the three-dimensional structure may include a pair of current collectors 100 and an electrolyte 300.

$$C = k {ε}_{0} \frac{A}{d} \qquad [ Equation 1 ]$$

k: the dielectric constant of the dielectric ε₀: the free space permittivity
A: the area of the current collector d: the interval between the pair of current collectors

Referring to [Equation 1], when the dielectric constant of the dielectric (k) and the free space permittivity (ε₀) are constant, the size of the electric capacitance (C) may increase as the area of the current collector (A) becomes larger or the interval between the pair of current collectors (d) becomes smaller. Reducing the interval between the current collectors (d) or increasing the area of the current collector (A) may have limitations in a limited space. In the electrode 1 having a current collector that has a three-dimensional structure, the capacity per unit area regardless of the area of the current collector (A) is capable of being increased by using a characteristic in which the charges (ions) and so on are concentrated on a sharp portion.

The pair of current collectors 100 may be positioned parallel to each other at a predetermined interval. In the pair of current collectors 100, a ‘+’ charge may be accumulated on the current collector connected to a positive electrode and a ‘−’ charge may be accumulated on the current collector connected to a negative electrode by a battery.

A three-dimensional sharp lightning rod structure may be formed on a surface of the pair of current collectors 100. In the pair of current collectors 100, by using a principle in which the sharper the edge, the higher the charge density in the actual charge distribution on a conductor surface, the amount of charges (ions) accumulated per unit area may be maximized by forming a three-dimensional sharp protrusion structure on the surface of the pair of the current collectors 100.

When an electric potential is viewed with two specific points of a surface of a conductor as 1 and 2, the surface of the conductor is an equipotential surface, so that V1=V2 is realized and

$$k \frac{{Q}_{1}}{{R}_{1}} = k \frac{{Q}_{2}}{{R}_{2}}$$

is realized since the equation V=kQ/R is realized. When the description described above is expressed in the form of a proportional equation, Q₁:Q₂=R₁:R₂ is realized.

Here, in order to look at the proportional equation from the perspective of the density of the charges (ions), when the density is σ in a conductive sphere with radius R,

$$k \frac{4 π {R}_{1}^{2} {σ}_{1}}{{R}_{1}} = k \frac{4 π {R}_{2}^{2} {σ}_{2}}{{R}_{2}}$$

is realized by using and substituting Q=4πR²σ into the proportional equation. The proportional equation σ₁:σ₂=R₁:R₂ is realized when the equation is summarized, and it can be seen that the charge density increases as the radius of curvature decreases. In the pair of current collectors 100, the density of charges (ions) can be maintained high in a three-dimensional sharp protrusion structure on the surface thereof. A high density of charges (ions) formed on the pair of current collectors 100 means an increase in the amount of charges (ions) accumulated per unit area, which means an increase in a battery capacity.

FIG. 5 is a graph showing an output voltage according to an input voltage applied to a monopole antenna when an interval between sharp end portions is 1 mm. Referring to FIG. 5, a discharge voltage of a structure without the sharp end portion is 10500 V, and a discharge voltage of a structure having the sharp end portion is 5000 V.

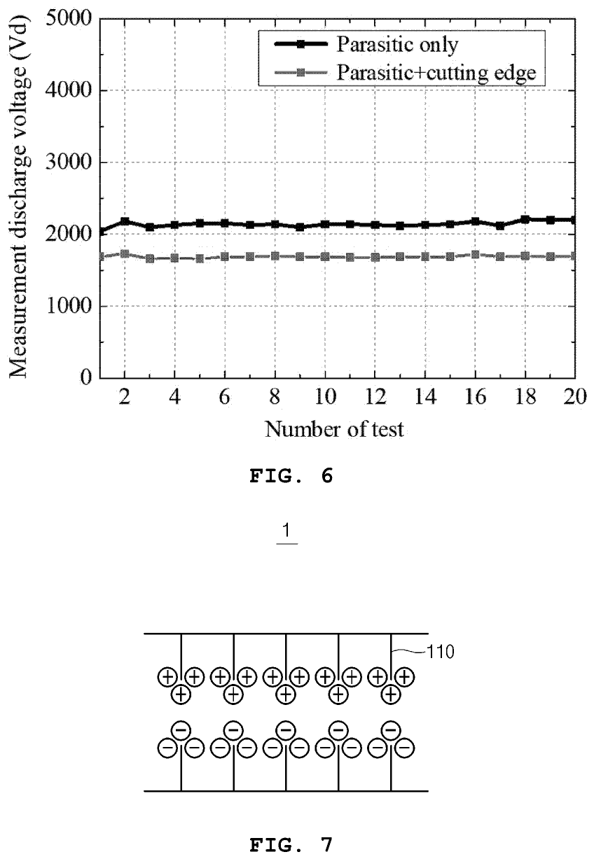

FIG. 6 is a graph showing a voltage at the time of discharge according to the presence or absence of a sharp end portion structure when an interval between optimized sharp end portions is 0.5 mm. Referring to FIG. 6, an average value of a discharge voltage was obtained through repeated experiments. A discharge voltage of a structure without the sharp end portion is 2141 V, and a discharge voltage of a structure having the sharp end portion is 1690 V. From this, it can be seen that charges are concentrated on the sharp protrusion portion and a discharge of external high output power easily occurs at a low external voltage. Therefore, referring to FIG. 5 and FIG. 6, a characteristic in which charges or ions are concentrated on the sharp protrusion portion can be confirmed.

FIG. 7 is a view illustrating an electrode 1 in which a sharp protrusion structure having a three-dimensional tack shape is formed on the surface of the current collector according to an embodiment of the present disclosure. Referring to FIG. 7, a sharp protrusion structure 110 having a three-dimensional tack shape may be formed on surfaces of the pair of current collectors 100.

The sharp protrusion structure 110 having the three-dimensional tack shape may have a ‘⊥’ shape. The sharp protrusion structure 110 having the three-dimensional tack shape may be formed of the surfaces of the pair of current collectors 100 such that the number or the interval of the sharp protrusion structure 110 having the three-dimensional tack shape is adjusted as required. The sharp protrusion structure 110 having the three-dimensional tack shape may have a single sharp portion. When the sharp protrusion structure 110 having the three-dimensional tack shape is formed on a positive electrode current collector, ‘+’ charges (ions) 3 may be concentrated on the single sharp portion. When the sharp protrusion structure 110 having the three-dimensional tack shape is formed on a negative electrode current collector, ‘−’ charges (ions) 5 may be concentrated on the single sharp portion.

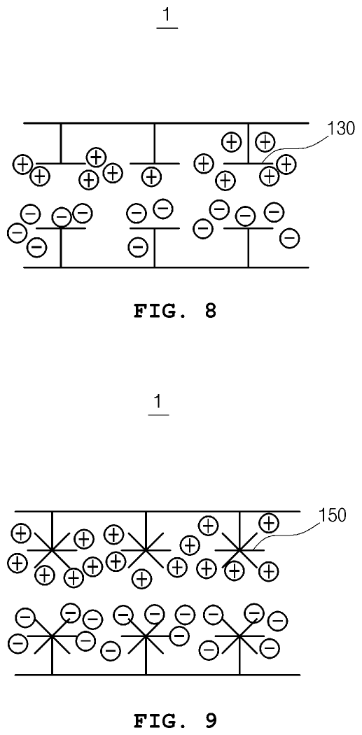

FIG. 8 is a view illustrating an electrode 1 in which a sharp protrusion structure having a three-dimensional T-shape is formed on the surface of the current collector according to an embodiment of the present disclosure. Referring to FIG. 8, a sharp protrusion structure 130 having a three-dimensional T-shape may be formed on surfaces of the pair of current collectors 100.

The sharp protrusion structure 130 having the three-dimensional T-shape may be formed of the surfaces of the pair of current collectors 100 such that the number or the interval of the sharp protrusion structure 130 having the three-dimensional T-shape is adjusted as required. The sharp protrusion structure 130 having the three-dimensional T-shape may have two sharp portions. When the sharp protrusion structure 130 having the three-dimensional T-shape is formed on a positive electrode current collector, the ‘+’ charges (ions) 3 may be concentrated on the two sharp portions. When the sharp protrusion structure 130 having the three-dimensional T-shape is formed on a negative electrode current collector, the ‘−’ charges (ions) 5 may be concentrated on the two sharp portions. Since the sharp protrusion structure 130 having the three-dimensional T-shape has more sharp portions than the sharp protrusion structure 110 having the three-dimensional tack shape, the density of charges (ions) per unit area of the sharp protrusion structure 130 may be higher than the density of charges (ions) per unit area of the sharp protrusion structure 110.

FIG. 9 is a view illustrating the electrode 1 in which a sharp protrusion structure having a three-dimensional dispersed shape is formed on the surface of the current collector according to an embodiment of the present disclosure. Referring to FIG. 9, a sharp protrusion structure 150 having a three-dimensional dispersed shape may be formed on the surfaces of the pair of current collectors 100.

The sharp protrusion structure 150 having the three-dimensional dispersed shape may have a ‘*’ shape. The sharp protrusion structure 150 having the three-dimensional dispersed shape may be formed of the surfaces of the pair of current collectors 100 such that the number or the interval of the sharp protrusion structure 150 having the three-dimensional dispersed shape is adjusted as required. The sharp protrusion structure 150 having the three-dimensional dispersed shape may have a plurality of sharp portions. When the sharp protrusion structure 150 having the three-dimensional dispersed shape is formed on a positive electrode current collector, the ‘+’ charges (ions) 3 may be concentrated on the plurality of sharp portions. When the sharp protrusion structure 150 having the three-dimensional dispersed shape is formed on a negative electrode current collector, the ‘−’ charges (ions) 5 may be concentrated on the plurality of sharp portions. Since the sharp protrusion structure 150 having the three-dimensional dispersed shape has more sharp portions than the sharp protrusion structure 110 having the three-dimensional tack shape and the sharp protrusion structure 130 having the three-dimensional T-shape, the density of charges (ions) per unit area of the sharp protrusion structure 130 may be higher than the density of charges (ions) per unit area of the sharp protrusion structure 110 and the density of charges (ions) per unit area of the sharp protrusion structure 130.

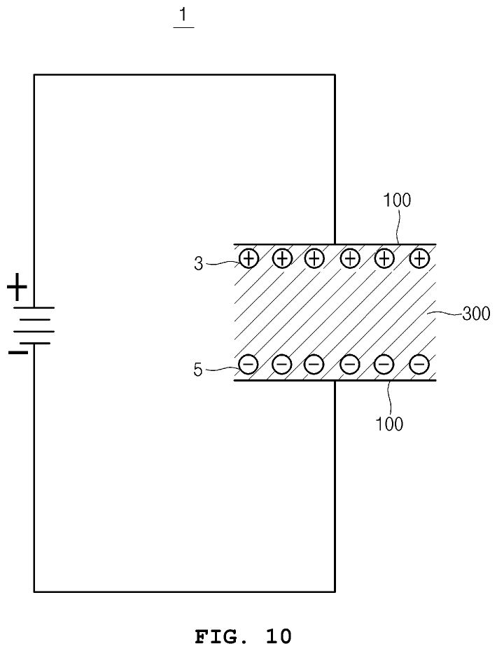

FIG. 10 is a view illustrating a configuration of a battery 2 using the electrode having the current collector that has the three-dimensional structure according to an embodiment of the present disclosure. Referring to FIG. 10, the battery 2 using the electrode having the current collector that has the three-dimensional structure may include the pair of current collectors 100 and the electrolyte 300.

Since the battery 2 using the electrode having the current collector that has the three-dimensional structure is using the electrode 1 having the current collector that has the three-dimensional structure, the electrode having the pair of current collectors 100 is equivalent to the electrode 1 having the current collector that has the three-dimensional structure.

The electrolyte 300 may be positioned between the pair of current collectors, and may be in contact with the pair of current collectors. The electrolyte 300 may be a liquid electrolyte or a solid electrolyte.

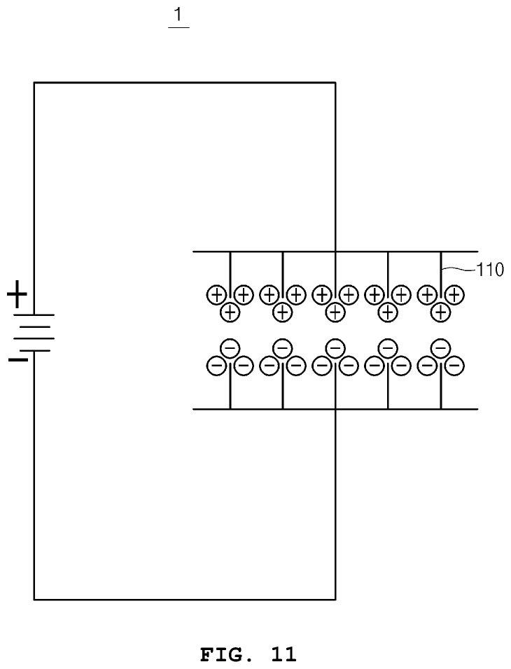

FIG. 11 shows the battery 2 using the electrode in which the sharp protrusion structure having the three-dimensional tack shape is formed the surface of the current collector according to an embodiment of the present disclosure. Referring to FIG. 11, the sharp protrusion structure 110 having the three-dimensional tack shape may be formed on the surfaces of the pair of current collectors 100. Since the battery 2 using the electrode having the current collector that has the three-dimensional structure is using the electrode 1 having the current collector that has the three-dimensional structure, a function of the sharp protrusion structure 110 having the three-dimensional tack shape is equivalent to a function of the electrode 1 having the current collector that has the three-dimensional structure.

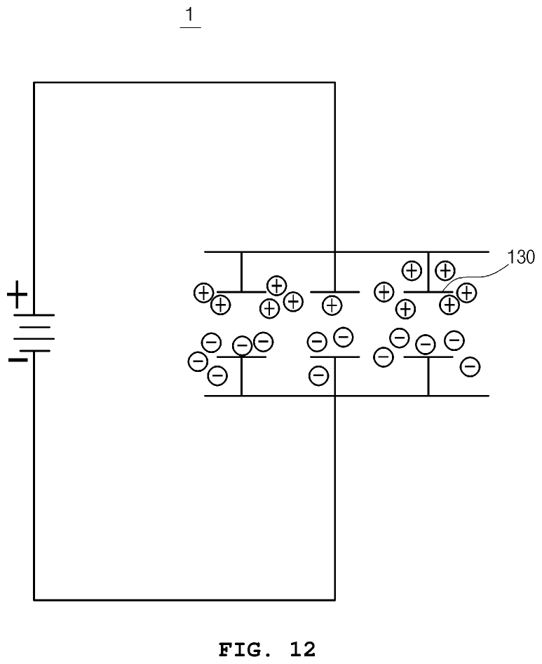

FIG. 12 shows the battery 2 using the electrode in which the sharp protrusion structure having the three-dimensional T-shape is formed the surface of the current collector according to an embodiment of the present disclosure. Referring to FIG. 12, the sharp protrusion structure 130 having the three-dimensional T-shape may be formed on the surfaces of the pair of current collectors 100. Since the battery 2 using the electrode having the current collector that has the three-dimensional structure is using the electrode 1 having the current collector that has the three-dimensional structure, a function of the sharp protrusion structure 130 having the three-dimensional T-shape is equivalent to the function of the electrode 1 having the current collector that has the three-dimensional structure.

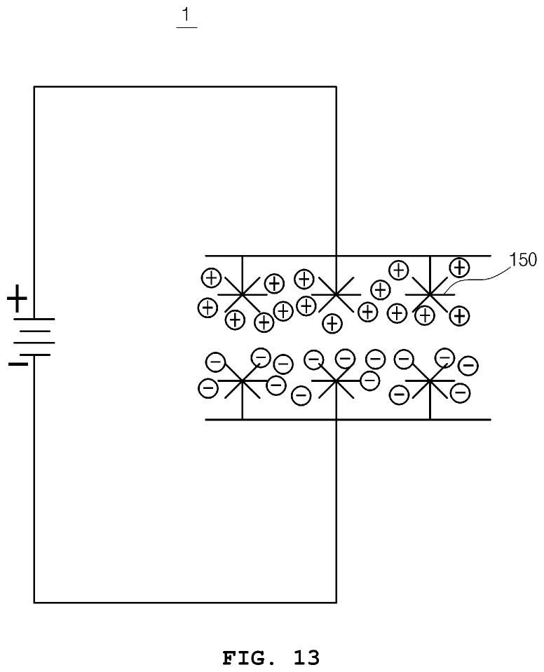

FIG. 13 shows the battery using the electrode in which the sharp protrusion structure having the three-dimensional dispersed shape is formed on the surface of the current collector according to an embodiment of the present disclosure. Referring to FIG. 13, the sharp protrusion structure 150 having the three-dimensional ‘*’shape may be formed on the surfaces of the pair of current collectors 100. Since the battery 2 using the electrode having the current collector that has the three-dimensional structure is using the electrode 1 having the current collector that has the three-dimensional structure, a function of the sharp protrusion structure 150 having the three-dimensional ‘*’ shape is equivalent to the function of the electrode 1 having the current collector that has the three-dimensional structure.

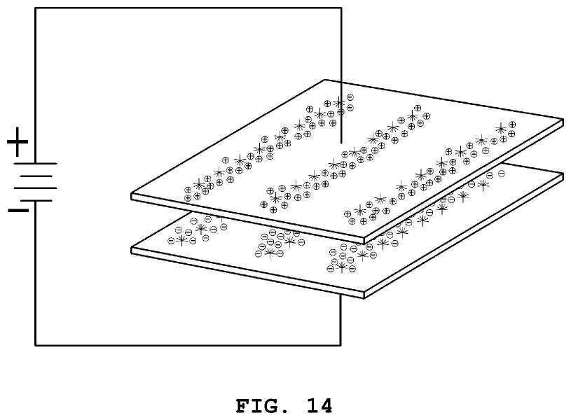

FIG. 14 is a view illustrating a configuration of the battery in which the current collector structure according to an embodiment of the present disclosure is illustrated in three dimensions. Referring to FIG. 14, the three-dimensional protrusion structure may be formed on the surfaces of the pair of current collectors 100 such that the number or the interval of the three-dimensional protrusion structure is adjusted as required.

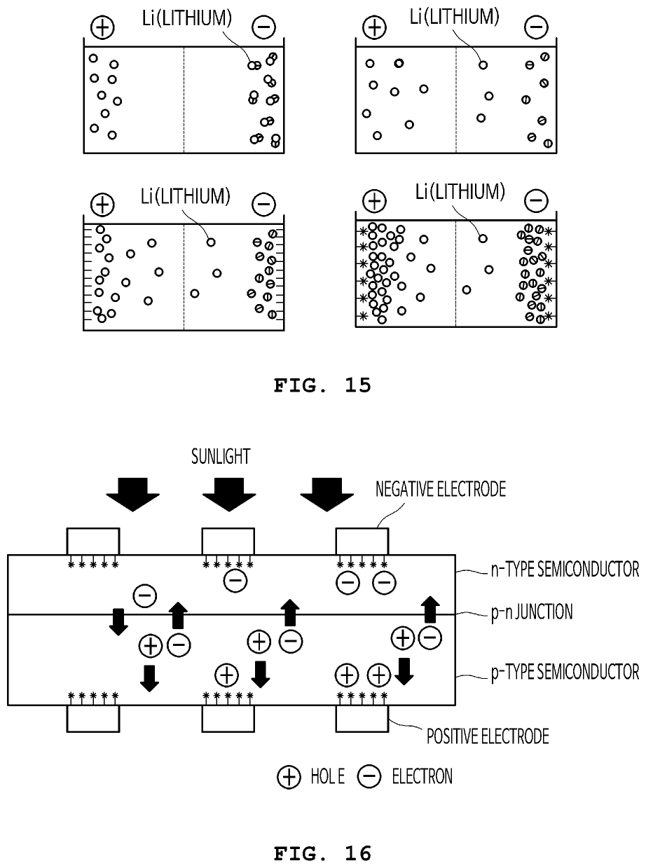

FIG. 15 is a view illustrating a configuration of lithium-ion batteries having the current collector that has the three-dimensional structure according to an embodiment of the present disclosure. Referring to FIG. 15, in the lithium-ion battery, when a negative electrode and a positive electrode are connected to each other, electrons separated from lithium-ions may be moved from the positive electrode to the negative electrode, and the battery is capable of being charged. By forming the three-dimensional sharp protrusion structure on the surfaces of the positive electrode and the negative electrode of the lithium-ion battery, the density of charges (ions) per unit area may be increased. Accordingly, the battery capacity of the lithium-ion battery may be increased.

FIG. 16 is a view illustrating a configuration of a solar cell having the current collector that has the three-dimensional structure according to an embodiment of the present disclosure. Referring to FIG. 16, by forming the three-dimensional sharp protrusion structure on the surfaces of the positive electrode and the negative electrode of the solar cell, a hydrogen fuel cell, and so on, the density of charges (ions) per unit area may be increased. Accordingly, the battery capacity of the solar cell may be increased.

Although the present disclosure has been described in detail through representative embodiments, those skilled in the art to which the present disclosure belongs will understand that various modifications of the described embodiments are possible within the spirit and scope of the present disclosure. Therefore, the spirit of the present disclosure should not be limited to the described embodiments, and all things equal or equivalent to the claims as well as the claims to be described later fall within the scope of the concept of the present disclosure.

### DESCRIPTION OF REFERENCE NUMERALS

1: Electrode having a current collector that has a three-dimensional structure
2: Battery using an electrode having a current collector that has a three-dimensional structure
3: ‘+’ charges (ions)
5. ‘−’ charges (ions)
100: Pair of current collectors
110: Sharp protrusion structure having a three-dimensional tack shape
130: Sharp protrusion structure having a three-dimensional T-shape
150: Sharp protrusion structure having a three-dimensional dispersed shape
300: Electrolyte

1. An electrode having a current collector that has a three-dimensional structure, the electrode comprising:
a pair of current collectors positioned parallel to each other at a predetermined interval,
wherein a three-dimensional sharp protrusion structure is formed on surfaces of the pair of current collectors, so that a charge distribution is concentrated on the three-dimensional sharp protrusion structure, thereby increasing a charging capacity per unit area of a battery.

2. The electrode of claim 1, wherein the three-dimensional sharp protrusion structure having a tack shape is formed on the surfaces of the pair of current collectors.

3. The electrode of claim 1, wherein the three-dimensional sharp protrusion structure having a T-shape is formed on the surfaces of the pair of current collectors.

4. The electrode of claim 1, wherein the three-dimensional sharp protrusion structure having a dispersed shape is formed on the surfaces of the pair of current collectors.

5. A battery using an electrode having a current collector that has a three-dimensional structure, the battery comprising:
a pair of current collectors positioned parallel to each other at a predetermined interval; and
an electrolyte positioned between the pair of current collectors, the electrolyte being in contact with the pair of current collectors,
wherein a three-dimensional sharp protrusion structure is formed on surfaces of the pair of current collectors, so that a charge distribution is concentrated on the three-dimensional sharp protrusion structure, thereby increasing a charging capacity per unit area.

6. The battery of claim 5, wherein the three-dimensional sharp protrusion structure having a tack shape is formed on the surfaces of the pair of current collectors.

7. The battery of claim 5, wherein the three-dimensional sharp protrusion structure having a T-shape is formed on the surfaces of the pair of current collectors.

8. The battery of claim 5, wherein the three-dimensional sharp protrusion structure having a dispersed shape is formed on the surfaces of the pair of current collectors.
